(19) United States
(12) Patent Application Publication
(10) Pub. No.: US 2024/0030037 A1
(43) Pub. Date: Jan. 25, 2024

(54) ETCHING METHOD

(71) Applicant: ADEKA CORPORATION, Tokyo (JP)

(72) Inventors: Yutaro AOKI, Tokyo (JP); Masayuki KIMURA, Tokyo (JP); Atsushi YAMASHITA, Tokyo (JP)

(21) Appl. No.: 18/023,158

(22) PCT Filed: Aug. 23, 2021
(86) PCT No.: PCT/JP2021/030739

§ 371 Date: Feb. 24, 2023

(30) Foreign Application Priority Data
Sep. 1, 2020 (JP) 2020-146816

(51) Int. Cl. H01L 21/311

(52) U.S. Cl. CPC H01L 21/31122

(57) ABSTRACT

Provided is a method of etching a metal oxide film in a laminate including a substrate and the metal oxide film formed on a surface thereof by an atomic layer etching method, the method including: a first step of introducing, into a treatment atmosphere storing the laminate, at least one oxidizable compound selected from the group consisting of: an alcohol compound; an aldehyde compound; and an ester compound; and a second step of introducing an oxidizing gas into the treatment atmosphere after the first step.

### TECHNICAL FIELD

The present invention relates to a method of etching a metal oxide film by an atomic layer etching method.

### BACKGROUND ART

At the time of the production of an apparatus such as a semiconductor apparatus, a fine pattern needs to be formed. To obtain the fine pattern, first, a high-quality thin-film needs to be formed, and for example, an atomic layer deposition method (sometimes referred to as “ALD method”) has been used as a production process. To further thin the high-quality thin-film formed by the ALD method, the thin-film needs to be etched. In such cases, however, the control of an etching amount of the order of several nanometers is required.

An atomic layer etching method (sometimes referred to as “ALE method”) has been attracting attention as a technology of enabling such etching. The ALE method is a technology including etching a metal atom-containing film formed on a substrate with an etching gas at an atomic layer level. Technologies based on such ALE method have been described in, for example, Patent Documents 1 to 3.

### CITATION LIST

### Patent Document

Patent Document 1: US 2012/0048831 A1
Patent Document 2: US 2018/0047577 A1
Patent Document 3: JP 2018-186269 A

### SUMMARY OF INVENTION

### Technical Problem

In Patent Document 1, there is a disclosure of an ALE method including using a chlorine gas as an etching gas. In Patent Document 2, there is a disclosure of an ALE method including using a hydrogen fluoride gas and a boron-containing gas as etching gases. However, each of those etching gases often does damage not only to a metal atom-containing film formed on a substrate but also to the substrate and a peripheral member. In addition, a large amount of a stainless-steel material has been used in a semiconductor-producing apparatus. There has been a problem in that the etching gases each corrode such stainless-steel material.

In Patent Document 3, there is a disclosure of an ALE method including using formic acid vapor as an etching gas. However, the formic acid vapor also has a strong metal corrosion property, and hence may do damage to, for example, a substrate or the stainless-steel material of a semiconductor-producing apparatus.

Accordingly, an object of the present invention is to provide a method of etching a metal oxide film by an ALE method without doing damage to, for example, a substrate or the stainless-steel material of a semiconductor-producing apparatus.

### Solution to Problem

The inventors of the present invention have made extensive investigations, and as a result, have found that the adoption of an ALE method including a specific step enables the etching of a metal oxide film with no damage to, for example, a substrate or the stainless-steel material of a semiconductor-producing apparatus.

That is, according to one embodiment of the present invention, there is provided a method of etching a metal oxide film in a laminate including a substrate and the metal oxide film formed on a surface thereof by an atomic layer etching method, the method including: a first step of introducing, into a treatment atmosphere storing the laminate, at least one oxidizable compound selected from the group consisting of: an alcohol compound; an aldehyde compound; and an ester compound; and a second step of introducing an oxidizing gas into the treatment atmosphere after the first step.

### Advantageous Effects of Invention

According to the present invention, the metal oxide film can be etched with high productivity with no damage to, for example, the substrate or the stainless-steel material of a semiconductor-producing apparatus.

### BRIEF DESCRIPTION OF DRAWINGS

FIG. 1 is a schematic diagram for illustrating an example of an apparatus to be used in an etching method of the present invention.

FIG. 2 is a schematic diagram of an apparatus to be used in an etching method of each of Comparative Examples.

### DESCRIPTION OF EMBODIMENTS

An etching method of the present invention includes: a step (oxidizable compound introduction step) of introducing, into a treatment atmosphere such as a chamber storing a laminate including a substrate and a metal oxide film formed on its surface, at least one oxidizable compound selected from the group consisting of: an alcohol compound; an aldehyde compound; and an ester compound; and a step (oxidizing gas introduction step) of introducing an oxidizing gas into the treatment atmosphere after the oxidizable compound introduction step. The etching method of the present invention includes a step (evacuation step) of evacuating a gas in the treatment atmosphere such as the chamber at each of the following stages as required: a stage between the oxidizable compound introduction step and the oxidizing gas introduction step; and a stage after the oxidizing gas introduction step. In the etching method of the present invention, the oxidizable compound introduction step, the evacuation step, the oxidizing gas introduction step, and the other evacuation step are sequentially performed as one cycle, and the metal oxide film can be etched to a desired thickness by repeating the cycle. The etching method of the present invention may be performed in combination with the formation of a thin-film by an ALD method, and in this case, the etching method can be performed without removal of the laminate from the treatment atmosphere such as the chamber. In addition, in the etching method of the present invention, the production amount of an etching gas may be controlled by the adsorption amount of the oxidizable compound. Accordingly, the etching method of the present invention may be suitably used in an etching process requiring microprocessing.

The respective steps of the etching method of the present invention are described below.

(Oxidizable Compound Introduction Step)

The oxidizable compound introduction step is a step of introducing, into the treatment atmosphere such as the chamber storing the laminate including the substrate and the metal oxide film formed on its surface, at least one oxidizable compound selected from the group consisting of: the alcohol compound; the aldehyde compound; and the ester compound.

Although the oxidizable compound may be introduced into the treatment atmosphere under any one of a liquid state or a gaseous state, the oxidizable compound in a gaseous state is preferably caused to act on (chemically adsorb to) the metal oxide film after the introduction. At this time, heat may be applied by heating the laminate or heating the inside of the treatment atmosphere. When the oxidizable compound in a gaseous state is introduced into the treatment atmosphere, the oxidizable compound is vaporized in a container in which the oxidizable compound is stored or a connecting portion for connecting the container and the chamber to each other by heating and/or decompression, followed by introduction into the treatment atmosphere. At the time of the introduction of the oxidizable compound in a gaseous state, an inert gas, such as argon, nitrogen, or helium, may be used as a carrier gas as required. When the oxidizable compound in a liquid state is introduced into the treatment atmosphere, the introduced oxidizable compound in a liquid state only needs to be vaporized by heating and/or decompressing the inside of the treatment atmosphere.

A pressure in the treatment atmosphere when the oxidizable compound introduction step is performed is preferably from 1 Pa to 10,000 Pa, more preferably from 10 Pa to 1,000 Pa. In addition, a temperature in the treatment atmosphere is set to preferably from 100° C. to 500° C., more preferably from 150° C. to 400° C., particularly preferably from 200° C. to 350° C. from the viewpoint that the metal oxide film can be etched with high productivity in the subsequent oxidizing gas introduction step.

Examples of the alcohol compound include: alkyl alcohols, such as methanol, ethanol, propanol, isopropyl alcohol, butanol, secondary butyl alcohol, isobutyl alcohol, tertiary butyl alcohol, pentyl alcohol, isopentyl alcohol, and tertiary pentyl alcohol; ether alcohols, such as 2-methoxyethanol, 2-ethoxyethanol, 2-butoxyethanol, 2-(2-methoxyethoxy)ethanol, 2-methoxy-1-methylethanol, 2-methoxy-1,1-dimethylethanol, 2-ethoxy-1,1-dimethylethanol, 2-isopropoxy-1,1-dimethylethanol, 2-butoxy-1,1-dimethylethanol, 2-(2-methoxyethoxy)-1,1-dimethylethanol, 2-propoxy-1,1-diethylethanol, 2-s-butoxy-1,1-diethylethanol, and 3-methoxy-1,1-dimethylpropanol; and dialkylamino alcohols, such as dimethylaminoethanol, ethylmethylaminoethanol, diethylaminoethanol, dimethylamino-2-pentanol, ethylmethylamino-2-pentanol, dimethylamino-2-methyl-2-pentanol, ethylmethylamino-2-methyl-2-pentanol, and diethylamino-2-methyl-2-pentanol.

Examples of the aldehyde compound include formaldehyde, acetaldehyde, propionaldehyde, butanal, pentanal, hexanal, heptanal, octanal, nonanal, decanal, and benzaldehyde.

Examples of the ester compound include methyl butyrate, methyl salicylate, ethyl formate, ethyl butyrate, ethyl acetate, ethyl caproate, pentyl acetate, isopentyl acetate, pentyl valerate, pentyl butyrate, and octyl acetate.

The oxidizable compound is preferably the alcohol compound, more preferably an alcohol compound having 1 to 5 carbon atoms, particularly preferably methanol, ethanol, or tertiary butyl alcohol from the viewpoint that the metal oxide film can be etched with high productivity in the subsequent oxidizing gas introduction step. In addition, the oxidizable compound is preferably free of any fluorine atom from the viewpoint that no damage is done to, for example, the substrate or the stainless-steel material of a semiconductor-producing apparatus.

Methods of synthesizing the alcohol compound, the aldehyde compound, and the ester compound described above are not particularly limited, and the compounds may be synthesized by using well-known and general methods of synthesizing an alcohol compound, an aldehyde compound, and an ester compound. In addition, compounds commercially available as reagents may be used.

The oxidizable compound to be used in the present invention is prevented from containing impurity metal elements, impurity halogens such as fluorine, and impurity organic substances to the extent possible. The content of each of the impurity metal elements is preferably 100 ppb or less, more preferably 10 ppb or less, and the total content thereof is preferably 1 ppm or less, more preferably 100 ppb or less. In particular, when the metal oxide film is used as a gate insulating film, a gate film, or a barrier layer of an LSI, it is required to reduce the contents of alkali metal elements and alkaline-earth metal elements that influence the electrical characteristics of the etched metal oxide film. The content of the impurity halogens is preferably 100 ppm or less, more preferably 10 ppm or less, most preferably 1 ppm or less. The total content of the impurity organic substances is preferably 500 ppm or less, more preferably 50 ppm or less, most preferably 10 ppm or less.

In addition, the oxidizable compound to be used in the present invention is preferably prevented from containing particles to the extent possible in order to reduce or prevent the particle contamination of the etched metal oxide film. Specifically, in particle measurement with a light scattering liquid particle detector in a liquid phase, it is preferred that the number of particles larger than 0.3 μm be 100 or less in 1 mL of the liquid phase, it is more preferred that the number of particles larger than 0.2 μm be 1,000 or less in 1 mL of the liquid phase, and it is most preferred that the number of particles larger than 0.2 μm be 100 or less in 1 mL of the liquid phase.

A material for the substrate is not particularly limited, but examples thereof include: silicon; ceramics, such as silicon nitride, titanium nitride, tantalum nitride, titanium oxide, titanium nitride, ruthenium oxide, zirconium oxide, hafnium oxide, and lanthanum oxide; glass; and metals. The shape of the substrate is, for example, a plate shape, a spherical shape, a fibrous shape, or a scaly shape. The surface of the substrate may be planar, or may have a three-dimensional structure such as a trench structure.

A method of forming the metal oxide film is not particularly limited, and examples thereof may include: a sputtering method; an ion plating method; a MOD method, such as a coating thermal decomposition method or a sol-gel method; a CVD method; and an ALD method. A metal oxide film formed by the ALD method is preferred from the viewpoint that the amount of impurities in the film is small, and hence an etching rate is stabilized. A laminate including a metal film formed on the surface of the substrate by any one of the above-mentioned methods may be used instead of the metal oxide film. When the laminate including the metal film is used, the metal film is oxidized in advance with an oxidizing gas, such as oxygen or ozone, before the oxidizable compound introduction step. Oxygen or ozone is preferred as the oxidizing gas to be used herein. After the oxidization of the metal film, the oxidizable compound introduction step is preferably performed after the oxidizing gas has been removed from the treatment atmosphere to the extent possible by purging the inside of the treatment atmosphere with an inert gas, such as argon or nitrogen.

The thickness of the metal oxide film, which is not particularly limited, is typically from 0.1 nm to 100 nm.

The kind of a metal for forming the metal oxide film is not particularly limited, but examples thereof include titanium, aluminum, zirconium, copper, cobalt, molybdenum, ruthenium, germanium, magnesium, tin, hafnium, scandium, gallium, iron, and zinc. Those metals for forming the metal oxide films may be used alone or in combination thereof.

(Evacuation Step)

After the oxidizable compound introduction step, the oxidizable compound in a gaseous state that has not adsorbed to the surface of the metal oxide film is evacuated from the inside of the chamber. At this time, although it is ideal to completely evacuate the oxidizable compound in a gaseous state from the inside of the chamber, it is not necessarily required to completely evacuate the compound. As an evacuation method, there are given, for example, a method including purging the inside of the chamber with an inert gas, such as helium, nitrogen, or argon, a method including performing evacuation by decompressing the inside of the chamber, and a combination of these methods. A decompression degree when decompression is performed falls within the range of preferably from 0.01 Pa to 300 Pa, more preferably from 0.01 Pa to 100 Pa.

(Oxidizing Gas Introduction Step)

The oxidizing gas introduction step is a step of introducing the oxidizing gas into the treatment atmosphere after the above-mentioned evacuation step. Although the mechanism of the etching is unclear, it is conceivable that the oxidizing gas reacts with the oxidizable compound that has chemically adsorbed to the metal oxide film to produce an etching gas in situ, and hence the metal oxide film is etched. At this time, heat may be applied by heating the laminate or heating the inside of the treatment atmosphere. At the time of the introduction of the oxidizing gas, an inert gas, such as argon, nitrogen, or helium, may be used as a carrier gas as required.

A pressure in the treatment atmosphere when the oxidizing gas introduction step is performed is preferably from 1 Pa to 10,000 Pa, more preferably from 10 Pa to 1,000 Pa. In addition, a temperature in the treatment atmosphere is set to preferably from 100° C. to 500° C., more preferably from 150° C. to 400° C., particularly preferably from 200° C. to 350° C. from the viewpoint that the metal oxide film can be etched with high productivity.

Examples of the oxidizing gas to be used in the present invention include oxygen, ozone, water vapor, hydrogen peroxide, nitrogen monoxide, and nitrous oxide. One kind of oxidizing gas may be used alone or two or more kinds thereof may be used in combination in the present invention. In addition, the oxidizing gas is preferably free of any fluorine atom from the viewpoint that no damage is done to, for example, the substrate or the stainless-steel material of a semiconductor-producing apparatus.

When one kind of oxidizing gas is used in the present invention, oxygen, ozone, or water vapor is preferred, and ozone is more preferred from the viewpoint that the metal oxide film can be etched with high productivity. When two or more kinds of oxidizing gases are used in the present invention, the gases preferably include ozone and any other oxidizing gas from the viewpoint that the metal oxide film can be etched with high productivity.

(Evacuation Step)

After the above-mentioned oxidizing gas introduction step, the unreacted oxidizing gas and a by-product gas are evacuated from the inside of the chamber. At this time, although it is ideal to completely evacuate the oxidizing gas and the by-product gas from the inside of the chamber, it is not necessarily required to completely evacuate the gases. An evacuation method and a decompression degree when decompression is performed are the same as those of the evacuation step after the oxidizable compound introduction step described above.

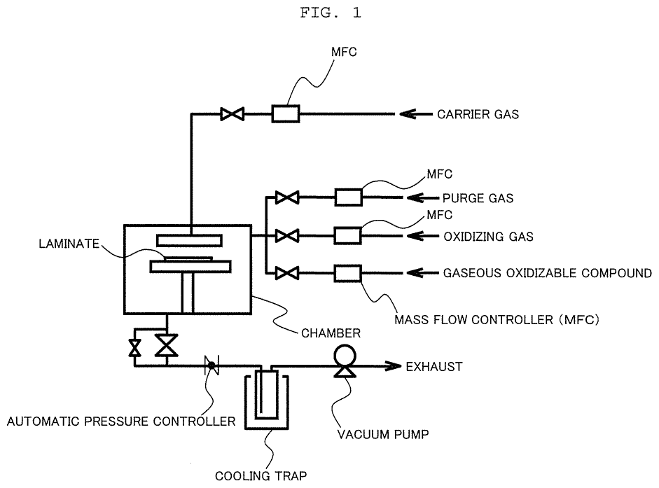

Such an apparatus as illustrated in FIG. 1, the apparatus including a chamber that can introduce the oxidizing gas, the oxidizable compound in a gaseous state, and the carrier gas into a system, and can evacuate the inside of the system with a purge gas, may be used as an apparatus for performing the etching method of the present invention. In addition, the etching method of the present invention may be performed in a film formation chamber in a well-known ALD apparatus. The oxidizing gas and the oxidizable compound in a gaseous state may be introduced into the film formation chamber in the ALD apparatus from separate ports, or may be introduced thereinto through a shower head.

In a related-art etching method, the contamination of a substrate component due to substrate corrosion and the halogen contamination thereof may occur, and moreover, a metal oxide film may be partially reduced depending on the kind of an etchant. In contrast, in the etching method of the present invention, such phenomena can be suppressed, and hence a high-quality metal oxide film having high purity can be obtained. Accordingly, the metal oxide film of the present invention may be suitably used in the production of various semiconductor elements each requiring a high-purity metal oxide film.

### EXAMPLES

Now, the present invention is described in more detail by way of Examples and Comparative Examples. However, the present invention is by no means limited to the following Examples and the like.

### Example 1

The atomic layer etching of a molybdenum oxide film formed on a silicon wafer was performed by using methanol as an oxidizable compound and an ozone gas as an oxidizing gas, and by using an apparatus illustrated in FIG. 1 under the following conditions and through the following steps. A change in thickness of the film before and after the atomic layer etching was observed by a fluorescent X-ray analysis method and with a scanning electron microscope. When the change in thickness of the film before and after the etching was measured, the thickness of the molybdenum oxide film reduced by 20.5 nm, and hence it was found that a thickness that was able to be etched per cycle was 0.68 nm. In addition, no corrosion of a stainless-steel material used in the apparatus was observed.

(Conditions)
Laminate: A product obtained by forming the molybdenum oxide film on the silicon wafer
Reaction temperature (silicon wafer temperature): 275° C.
Oxidizable compound: Methanol
Oxidizing gas: Ozone

(Steps)

A series of steps including the following (1) to (4) was defined as one cycle, and this cycle was repeated 30 times.
(1) The oxidizable compound vaporized under the conditions of 23° C. and 100 Pa was introduced into a chamber, and the oxidizable compound was caused to adsorb to the surface of the molybdenum oxide film at a system pressure of 100 Pa for 5 seconds.
(2) The oxidizable compound that was not adsorbed thereto was evacuated from the inside of the chamber through argon purging for 60 seconds.
(3) The oxidizing gas was introduced into the chamber to perform the etching at a system pressure of 100 Pa for 20 seconds.
(4) The unreacted oxidizing gas and a by-product gas were evacuated from the inside of the chamber through argon purging for 60 seconds.

### Example 2

Atomic layer etching was performed in the same manner as in Example 1 except that ethanol was used instead of methanol as an oxidizable compound. When a change in thickness of the film before and after the atomic layer etching was measured, the thickness of the molybdenum oxide film reduced by 17.0 nm, and hence it was found that a thickness that was able to be etched per cycle was 0.57 nm. In addition, no corrosion of a stainless-steel material used in the apparatus was observed.

### Example 3

Atomic layer etching was performed in the same manner as in Example 1 except that: a product obtained by forming a cobalt oxide film on a silicon wafer was used as a laminate; and tertiary butyl alcohol was used instead of methanol as an oxidizable compound. When a change in thickness of the film before and after the atomic layer etching was measured, the thickness of the cobalt oxide film reduced by 15.5 nm, and hence it was found that a thickness that was able to be etched per cycle was 0.52 nm. In addition, no corrosion of a stainless-steel material used in the apparatus was observed.

### Example 4

Atomic layer etching was performed in the same manner as in Example 1 except that acetaldehyde was used instead of methanol as an oxidizable compound. When a change in thickness of the film before and after the atomic layer etching was measured, the thickness of the molybdenum oxide film reduced by 14.5 nm, and hence it was found that a thickness that was able to be etched per cycle was 0.48 nm. In addition, no corrosion of a stainless-steel material used in the apparatus was observed.

### Example 5

Atomic layer etching was performed in the same manner as in Example 1 except that: a product obtained by forming a titanium oxide film on a silicon wafer was used as a laminate; and ethyl acetate was used instead of methanol as an oxidizable compound. When a change in thickness of the film before and after the atomic layer etching was measured, the thickness of the titanium oxide film reduced by 14.0 nm, and hence it was found that a thickness that was able to be etched per cycle was 0.47 nm. In addition, no corrosion of a stainless-steel material used in the apparatus was observed.

### Example 6

Atomic layer etching was performed in the same manner as in Example 1 except that: a product obtained by forming a copper oxide film on a silicon wafer was used as a laminate; and tertiary butyl alcohol was used instead of methanol as an oxidizable compound. When a change in thickness of the film before and after the atomic layer etching was measured, the thickness of the copper oxide film reduced by 15.0 nm, and hence it was found that a thickness that was able to be etched per cycle was 0.50 nm. In addition, no corrosion of a stainless-steel material used in the apparatus was observed.

### Comparative Example 1

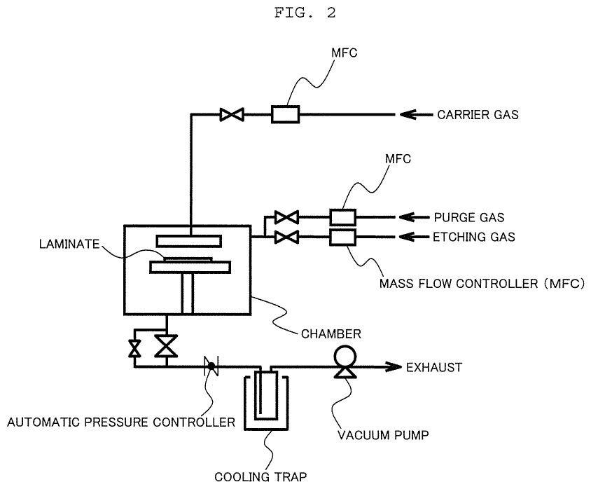

The atomic layer etching of a molybdenum oxide film formed on a silicon wafer was performed by using hydrogen fluoride as an etching gas, and by using an apparatus illustrated in FIG. 2 under the following conditions and through the following steps. A change in thickness of the film before and after the atomic layer etching was observed by a fluorescent X-ray analysis method and with a scanning electron microscope. When the change in thickness of the film before and after the atomic layer etching was measured, the thickness of the molybdenum oxide film reduced by 8.5 nm, and hence it was found that a thickness that was able to be etched per cycle was 0.28 nm. However, corrosion of a stainless-steel material used in the apparatus was observed.

(Conditions)
Laminate: A product obtained by forming the molybdenum oxide film on the silicon wafer
Reaction temperature (silicon wafer temperature): 275° C.
Etching gas: Hydrogen fluoride

(Steps)

A series of steps including the following (1) and (2) was defined as one cycle, and this cycle was repeated 30 times.
(1) The etching gas was introduced into a chamber to perform the etching at a system pressure of 100 Pa for 20 seconds.
(2) The unreacted etching gas and a by-product gas were evacuated from the inside of the chamber through argon purging for 60 seconds.

### Comparative Example 2

Atomic layer etching was performed in the same manner as in Comparative Example 1 except that formic acid vapor was used instead of hydrogen fluoride as an etching gas. When a change in thickness of the film before and after the atomic layer etching was measured, the thickness of the molybdenum oxide film reduced by 7.5 nm, and hence it was found that a thickness that was able to be etched per cycle was 0.25 nm. However, corrosion of a stainless-steel material used in the apparatus was observed.

It was found from the foregoing results that according to the present invention, a metal oxide film formed on a substrate was able to be etched with high productivity with no damage to a stainless-steel material used in a semiconductor-producing apparatus or the like.

1. A method of etching a metal oxide film in a laminate including a substrate and the metal oxide film formed on a surface thereof by an atomic layer etching method, the method comprising:
a first step of introducing, into a treatment atmosphere storing the laminate, at least one oxidizable compound selected from the group consisting of: an alcohol compound; an aldehyde compound; and an ester compound; and
a second step of introducing an oxidizing gas into the treatment atmosphere after the first step.

2. The etching method according to claim 1, wherein a temperature in the treatment atmosphere is set to 150° C. or more in the first step or the second step.

3. The etching method according to claim 1, wherein the oxidizing gas is at least one gas selected from the group consisting of: oxygen; ozone; water vapor; hydrogen peroxide; nitrogen monoxide; and nitrous oxide.

4. The etching method according to claim 1, wherein a metal for forming the metal oxide film is at least one metal selected from the group consisting of: titanium; aluminum; zirconium; copper; cobalt; molybdenum; ruthenium; germanium; magnesium; tin; hafnium; scandium; gallium; iron; and zinc.

5. The etching method according to claim 1, wherein the oxidizable compound is an alcohol compound having 1 to 5 carbon atoms.

6. The etching method according to claim 1, wherein the oxidizable compound and the oxidizing gas are each free of any fluorine atom.

7. A metal oxide film, which is etched by the etching method of claim 1.
